(19) United States
(12) Patent Application Publication
(10) Pub. No.: US 2026/0271698 A1
(43) Pub. Date: Sep. 10, 2026

(54) SEMICONDUCTOR PACKAGE AND FABRICATING METHOD THEREOF

(71) Applicant: SK hynix Inc., Gyeonggi-do (KR)

(72) Inventor: Heon Yong CHANG, Gyeonggi-do (KR)

(21) Appl. No.: 19/243,617

(22) Filed: Jun. 19, 2025

(30) Foreign Application Priority Data
Mar. 7, 2025 (KR) 10-2025-0029474

(51) Int. Cl. H10W 20/42; H10W 74/10; H10W 90/00; H10W 70/60; H10W 72/20; H10W 74/15

(52) U.S. Cl. CPC H10W 20/42; H10W 74/131; H10W 90/00; H10W 70/60; H10W 72/244; H10W 74/15; H10W 90/734

(57) ABSTRACT

A semiconductor package according to embodiments of the present disclosure may include a base chip; a first redistribution layer disposed on the base chip; a first bump disposed on the first redistribution layer; a plurality of core chips stacked upon each other; a second redistribution layer disposed below the plurality of the core chips; a plurality of bonding wires disposed under the plurality of core chips, and respectively connecting the plurality of core chips and the second redistribution layer; a molding layer disposed on the second redistribution layer, and disposed to cover the plurality of core chips and surround the plurality of bonding wires; and a second bump disposed under the second redistribution layer and bonded onto the first bump.

### CROSS-REFERENCE TO RELATED APPLICATION

The present application claims priority under 35 U.S.C. §119(a) to Korean Patent Application No. 10-2025-0029474 filed on March 7, 2025, which is incorporated herein by reference in its entirety.

### BACKGROUND

### 1. Technical Field

Embodiments of the present disclosure relate to a semiconductor technology, and more particularly, to a semiconductor package and a method of fabricating the same.

### 2. Related Art

Electronic products are required to process high-capacity data while becoming increasingly smaller in volume. Accordingly, there is a growing need to increase the degree of integration of semiconductor devices used in electronic products. Because it is difficult to satisfy required functions with just a single semiconductor chip due to limitations in integration technology, semiconductor packages are manufactured using a plurality of semiconductor chips.

Even when a semiconductor package includes a plurality of semiconductor chips, the semiconductor package is required to be fabricated to a specified thickness (or to be thinner than a specified thickness) depending on the requirements of an application in which the semiconductor package is mounted.

### SUMMARY

Embodiments of the present disclosure are directed to providing a semiconductor package capable of reducing thickness, and a method of fabricating the same.

Objects of embodiments of the disclosure are not limited to those set forth herein, and other unmentioned objects will be apparent to one of ordinary skill in the art from the following description.

In an embodiment, a semiconductor package may include: a base chip; a first redistribution layer disposed on the base chip, a first bump disposed on the first redistribution layer, a plurality of core chips stacked upon each other, a second redistribution layer disposed below the plurality of core chips, a plurality of bonding wires respectively disposed under the plurality of core chips, and respectively connecting the plurality of core chips and the second redistribution layer, a molding layer disposed on the second redistribution layer, and disposed to cover the plurality of core chips and surround the plurality of bonding wires and a second bump disposed under the second redistribution layer and bonded onto the first bump.

In an embodiment, a method of fabricating a semiconductor package may include: forming a first redistribution layer on a base chip, forming a first bump on the first redistribution layer, stacking a plurality of core chips; forming a plurality of bonding wires on the plurality of core chips, forming a molding layer that covers the plurality of core chips and surrounds the plurality of bonding wires, forming a second redistribution layer on the molding layer and the plurality of bonding wires, forming a second bump on the second redistribution layer, and bonding the second bump onto the first bump.

In an embodiment, a semiconductor package may include: a plurality of core chips stacked in a stair step formation, a plurality of bonding wires, with lengths of each bonding wire defined by a place in an arrangement in the stair step formation, a first redistribution layer disposed on a base chip, a first bump disposed on the first redistribution layer; a molding layer covering the plurality of core chips and the plurality of bonding wires, a second redistribution layer disposed below the molding layer and the plurality of bonding wires, and a second bump disposed under the second redistribution layer and bonded onto the first bump.

According to the embodiments of the present disclosure, a semiconductor package capable of reducing thickness and a method of fabricating the same may be provided.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a cross-sectional view of a semiconductor package according to an embodiment of the present disclosure.

FIG. 2 is a flowchart showing a method of fabricating a semiconductor package according to an embodiment of the present disclosure.

FIG. 3 to FIG. 13 are cross-sectional views illustrating the method of fabricating a semiconductor package according to the embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

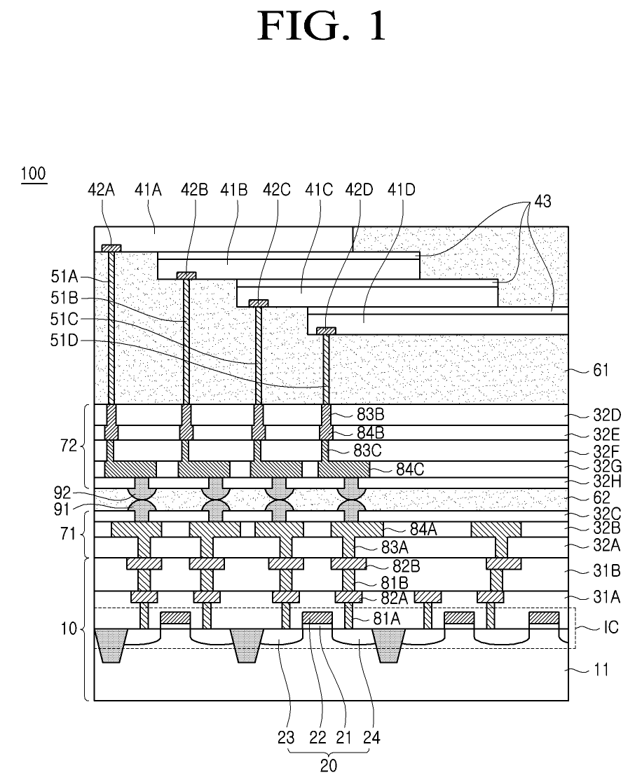

FIG. 1 is a cross-sectional view of a semiconductor package 100 according to an embodiment of the present disclosure.

Referring to FIG. 1, the semiconductor package 100 according to the embodiment of the present disclosure may include a base chip 10, a plurality of core chips 41A, 41B, 41C and 41D, bonding wires 51A, 51B, 51C and 51D, a molding layer 61, first and second redistribution layers 71 and 72, and first and second bumps 91 and 92. Additionally, the semiconductor package 100 according to the embodiment of the present disclosure may include an underfill member 62.

The base chip 10 may include a substrate 11, a first integrated circuit IC, insulating layers 31A and 31B and a first chip pad 82B.

The core chips 41A, 41B, 41C, and 41D may be memory chips, and the base chip 10 may be a logic chip for controlling the memory chips. The first integrated circuit IC may include individual elements for realizing the function of the logic chip. The individual element may include a transistor 20. The transistor 20 may include a gate insulating layer 21, a gate electrode 22, and first and second junction areas 23 and 24. The gate insulating layer 21 may be disposed on the substrate 11, and the gate electrode 22 may be disposed on the gate insulating layer 21. The first and second junction areas 23 and 24 may be disposed in the substrate 11 on both sides, respectively, of the gate electrode 22.

The insulating layers 31A and 31B may include a first insulating layer 31A and a second insulating layer 31B. The first insulating layer 31A may be disposed on the substrate 11 and cover the first integrated circuit IC.

A first via 81A and a wiring 82A may be disposed in the first insulating layer 31A. The lower surface and side surface of the wiring 82A may be surrounded by the first insulating layer 31A, and the upper surface of the wiring 82A may be exposed at the upper surface of the first insulating layer 31A. The first via 81A may be disposed under the wiring 82A. The first via 81A may vertically penetrate the first insulating layer 31A under the wiring 82A. The upper end of the first via 81A may be connected to the wiring 82A, and the lower end of the first via 81A may be connected to the first integrated circuit IC. The wiring 82A may be connected to the first integrated circuit IC through the first via 81A.

The second insulating layer 31B may be disposed on the first insulating layer 31A. The second insulating layer 31B may cover the first insulating layer 31A and the wiring 82A.

A second via 81B and the first chip pad 82B may be disposed in the second insulating layer 31B. The lower surface and side surface of the first chip pad 82B may be surrounded by the second insulating layer 31B, and the upper surface of the first chip pad 82B may be exposed at the upper surface of the second insulating layer 31B. The second via 81B may be disposed under the first chip pad 82B. The second via 81B may vertically penetrate the second insulating layer 31B under the first chip pad 82B. The upper end of the second via 81B may be connected to the first chip pad 82B, and the lower end of the second via 81B may be connected to the wiring 82A. The first chip pad 82B may be connected to the first integrated circuit IC through the second via 81B, the wiring 82A, and the first via 81A.

The first redistribution layer 71 may be disposed on the base chip 10. The first redistribution layer 71 may include first, second and third redistribution insulating layers 32A, 32B and 32C, a first redistribution via 83A and a first redistribution pattern 84A.

The first redistribution insulating layer 32A may be disposed on the base chip 10. The first redistribution insulating layer 32A may cover the upper surface of the base chip 10. The first redistribution via 83A may vertically penetrate the first redistribution insulating layer 32A and be connected to the first chip pad 82B.

The first redistribution pattern 84A may be disposed on the first redistribution via 83A and the first redistribution insulating layer 32A. The first redistribution pattern 84A may be connected to the first redistribution via 83A, and may be connected to the first chip pad 82B through the first redistribution via 83A. The first redistribution via 83A and the first redistribution pattern 84A may be integrally formed.

The second redistribution insulating layer 32B may be disposed on the first redistribution insulating layer 32A. The second redistribution insulating layer 32B may cover the upper surface of the first redistribution insulating layer 32A and surround the side surface of the first redistribution pattern 84A. The second redistribution insulating layer 32B may expose the upper surface of the first redistribution pattern 84A. The upper surface of the first redistribution pattern 84A and the upper surface of the second redistribution insulating layer 32B may be placed on the same plane. The second redistribution insulating layer 32B may include an insulating material that has an etching selectivity different from that of the first redistribution insulating layer 32A. The first redistribution insulating layer 32A may include nitride, and the second redistribution insulating layer 32B may include oxide.

The third redistribution insulating layer 32C may be disposed on the second redistribution insulating layer 32B. The third redistribution insulating layer 32C may cover the upper surface of the second redistribution insulating layer 32B and have an opening that exposes the first redistribution pattern 84A.

The first bump 91 may be disposed on the first redistribution pattern 84A exposed through the opening of the third redistribution insulating layer 32C. The first bump 91 may be a solder ball or a stack structure of a metal pillar and a solder layer.

The core chips 41A, 41B, 41C, and 41D may be stacked. The core chips 41A, 41B, 41C, and 41D may include a first core chip 41A, a second core chip 41B that is disposed under the first core chip 41A, a third core chip 41C that is disposed under the second core chip 41B, and a fourth core chip 41D that is disposed under the third core chip 41C. Among the first, second, third and fourth core chips 41A, 41B, 41C and 41D, the first core chip 41A may be disposed at the top and the fourth core chip 41D may be disposed at the bottom. In FIG. 1, the number of stacked core chips is four, but the present disclosure is not limited thereto. The present disclosure includes (or may be extrapolated to within the scope of the disclosure) all cases where the number of stacked core chips is two or more.

The first, second, third and fourth core chips 41A, 41B, 41C, and 41D may be memory chips. Each of the first, second, third and fourth core chips 41A, 41B, 41C, and 41D may include a second integrated circuit. The second integrated circuit may include memory cells. Second chip pads 42A, 42B, 42C, and 42D may be disposed close to the edges of the lower surfaces of the first, second, third and fourth core chips 41A, 41B, 41C, and 41D, respectively.

The first, second, third and fourth core chips 41A, 41B, 41C, and 41D may be stacked in a stepwise manner such that the second chip pads 42A, 42B, 42C, and 42D are exposed. As illustrated in FIG. 1, each of the second chip pads 42A, 42B, 42C, and 42D is disposed close to the left edge of the lower surface of a corresponding core chip, and the first, second, third and fourth core chips 41A, 41B, 41C, and 41D may be stacked in a stairway shape (for example, a stair step formation) in which the first, second, third and fourth core chips 41A, 41B, 41C, and 41D become farther in a rightward direction as they go down, such that the second chip pads 42A, 42B, 42C, and 42D are exposed.

An adhesive member 43 may be disposed on the upper surface of each of the second, third and fourth core chips 41B, 41C, and 41D. The first, second, third and fourth core chips 41A, 41B, 41C, and 41D may be attached to each other by the medium of adhesive members 43.

The bonding wires 51A, 51B, 51C, and 51D may be disposed under the first, second, third and fourth core chips 41A, 41B, 41C, and 41D. The bonding wires 51A, 51B, 51C, and 51D may include a first bonding wire 51A that is disposed under the first core chip 41A, a second bonding wire 51B that is disposed under the second core chip 41B, a third bonding wire 51C that is disposed under the third core chip 41C, and a fourth bonding wire 51D that is disposed under the fourth core chip 41D. The bonding wires 51A, 51B, 51C, and 51D may be arranged in a stair step formation corresponding to the stair step formation of the first, second, third and fourth core chips 41A, 41B, 41C, and 41D. The lengths of each bonding wire may be defined by a place of the particular bonding wire in an arrangement of the bonding wires 51A, 51B, 51C, and 51D in the stair step formation.

The first bonding wire 51A may be connected to the second chip pad 42A of the first core chip 41A. The first bonding wire 51A may vertically extend with its upper end connected to the second chip pad 42A of the first core chip 41A. The first bonding wire 51A may vertically extend or be vertically erected from the surface of the second chip pad 42A of the first core chip 41A.

The second bonding wire 51B may be connected to the second chip pad 42B of the second core chip 41B. The second bonding wire 51B may vertically extend with its upper end connected to the second chip pad 42B of the second core chip 41B. The second bonding wire 51B may vertically extend or be vertically erected from the surface of the second chip pad 42B of the second core chip 41B.

The third bonding wire 51C may be connected to the second chip pad 42C of the third core chip 41C. The third bonding wire 51C may vertically extend with its upper end connected to the second chip pad 42C of the third core chip 41C. The third bonding wire 51C may vertically extend or be vertically erected from the surface of the second chip pad 42C of the third core chip 41C.

The fourth bonding wire 51D may be connected to the second chip pad 42D of the fourth core chip 41D. The fourth bonding wire 51D may vertically extend with its upper end connected to the second chip pad 42D of the fourth core chip 41D. The fourth bonding wire 51D may vertically extend or be vertically erected from the surface of the second chip pad 42D of the fourth core chip 41D. The first, second, third and fourth bonding wires 51A, 51B, 51C and 51D may include gold (Au).

The molding layer 61 may seal the first, second, third and fourth core chips 41A, 41B, 41C, and 41D and the first, second, third and fourth bonding wires 51A, 51B, 51C, and 51D. The molding layer 61 may seal the first, second, third and fourth core chips 41A, 41B, 41C, and 41D and the first, second, third and fourth bonding wires 51A, 51B, 51C, and 51D to protect them from an external environment. The molding layer 61 includes an insulating layer. The insulating layer may include an epoxy molding compound (EMC). The epoxy molding compound may include resin and filler.

The molding layer 61 may expose the upper surface of the first core chip 41A. The upper surface of the molding layer 61 and the upper surface of the first core chip 41A may be placed on the same plane. Because the upper surface of the first core chip 41A is not covered with the molding layer 61, the heat generated when the first, second, third and fourth core chips 41A, 41B, 41C, and 41D operate may be dissipated to the outside through the upper surface of the first core chip 41A without interference from the molding layer 61.

The molding layer 61 may expose one side surface of the first core chip 41A and one side surface of the fourth core chip 41D. As illustrated in FIG. 1, the molding layer 61 may expose the left side surface of the first core chip 41A and the right side surface of the fourth core chip 41D.

The lower ends of the first, second, third and fourth bonding wires 51A, 51B, 51C, and 51D may be exposed at the lower surface of the molding layer 61. The second redistribution layer 72 may be disposed under the molding layer 61 and the first, second, third and fourth bonding wires 51A, 51B, 51C, and 51D.

The second redistribution layer 72 may include fourth, fifth, sixth, seventh and eighth redistribution insulating layers 32D, 32E, 32F, 32G, and 32H, second and third redistribution vias 83B and 83C, and second and third redistribution patterns 84B and 84C.

The fourth redistribution insulating layer 32D may be disposed under the molding layer 61. The fourth redistribution insulating layer 32D may cover the lower surface of the molding layer 61.

The second redistribution via 83B may vertically penetrate the fourth redistribution insulating layer 32D and be connected to a corresponding one of the first, second, third, and fourth bonding wires 51A, 51B, 51C, and 51D.

The second redistribution pattern 84B may be disposed under the second redistribution via 83B and the fourth redistribution insulating layer 32D. The second redistribution pattern 84B may be connected to the second redistribution via 83B. The second redistribution via 83B and the second redistribution pattern 84B may be integrally formed.

The fifth redistribution insulating layer 32E may be disposed under the fourth redistribution insulating layer 32D. The fifth redistribution insulating layer 32E may cover the lower surface of the fourth redistribution insulating layer 32D and surround the side surface of the second redistribution pattern 84B. The fifth redistribution insulating layer 32E may expose the lower surface of the second redistribution pattern 84B. The lower surface of the second redistribution pattern 84B and the lower surface of the fifth redistribution insulating layer 32E may be placed on the same plane. The fifth redistribution insulating layer 32E may include an insulating material that has an etching selectivity different from that of the fourth redistribution insulating layer 32D. The fourth redistribution insulating layer 32D may include nitride, and the fifth redistribution insulating layer 32E may include oxide.

The sixth redistribution insulating layer 32F may be disposed under the fifth redistribution insulating layer 32E. The sixth redistribution insulating layer 32F may cover the lower surface of the fifth redistribution insulating layer 32E.

The third redistribution via 83C may vertically penetrate the sixth redistribution insulating layer 32F and be connected to the second redistribution pattern 84B. The third redistribution pattern 84C may be disposed under the third redistribution via 83C and the sixth redistribution insulating layer 32F. The third redistribution pattern 84C may be connected to the third redistribution via 83C. The third redistribution via 83C and the third redistribution pattern 84C may be integrally formed.

The seventh redistribution insulating layer 32G may be disposed under the sixth redistribution insulating layer 32F. The seventh redistribution insulating layer 32G may cover the lower surface of the sixth redistribution insulating layer 32F and surround the side surface of the third redistribution pattern 84C. The seventh redistribution insulating layer 32G may expose the lower surface of the third redistribution pattern 84C. The lower surface of the third redistribution pattern 84C and the lower surface of the seventh redistribution insulating layer 32G may be placed on the same plane. The seventh redistribution insulating layer 32G may include an insulating material that has an etching selectivity different from that of the sixth redistribution insulating layer 32F. The sixth redistribution insulating layer 32F may include nitride, and the seventh redistribution insulating layer 32G may include oxide.

The eighth redistribution insulating layer 32H may be disposed under the seventh redistribution insulating layer 32G. The eighth redistribution insulating layer 32H may cover the lower surface of the seventh redistribution insulating layer 32G and have an opening that partially exposes the third redistribution pattern 84C.

The second bump 92 may be disposed under the third redistribution pattern 84C exposed through the opening of the eighth redistribution insulating layer 32H. The second bump 92 may be a solder ball or a stack structure of a metal pillar and a solder layer. The second bump 92 may be disposed on the first bump 91 and be bonded to the first bump 91.

The underfill member 62 may fill a space between the first redistribution layer 71 and the second redistribution layer 72. The underfill member 62 may surround the side surfaces of the first and second bumps 91 and 92.

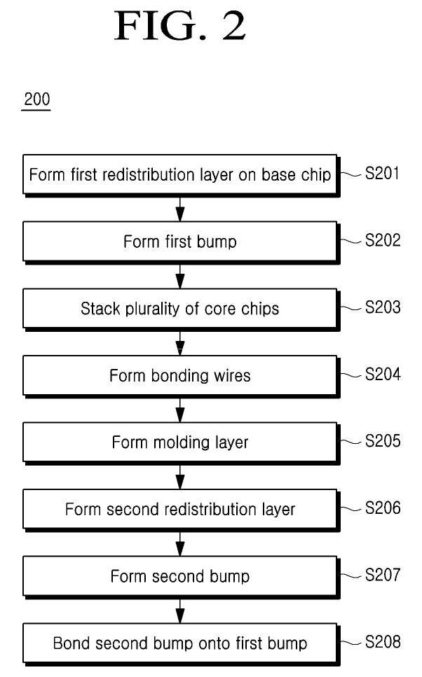

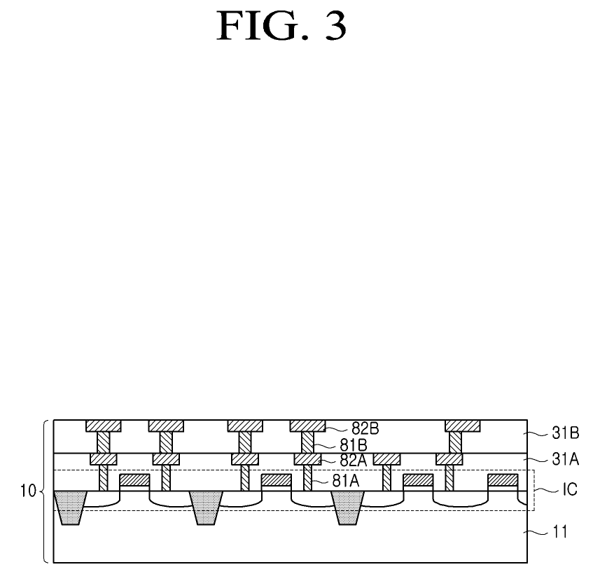

FIG. 2 is a flowchart showing a method 200 of fabricating a semiconductor package according to an embodiment of the present disclosure, and FIG. 3 to FIG. 13 are cross-sectional views illustrating the method of fabricating a semiconductor package according to the embodiment of the present disclosure.

Referring to FIG. 2, the method 200 of fabricating a semiconductor package according to the embodiment of the present disclosure may include a step of forming a first redistribution layer on a base chip (S201), a step of forming a first bump on the first redistribution layer (S202), a step of stacking a plurality of core chips (S203), a step of forming bonding wires on the core chips (S204), a step of forming a molding layer (S205), a step of forming a second redistribution layer on the molding layer and the bonding wires (S206), a step of forming a second bump on the second redistribution layer (S207), and a step of bonding the second bump onto the first bump (S208).

Referring to FIG. 3, a base chip 10 may be defined.

The base chip 10 may include a substrate 11, a first integrated circuit IC, insulating layers 31A and 31B and a first chip pad 82B.

The first integrated circuit IC may be disposed on the substrate 11. The first integrated circuit IC may include individual elements for realizing the function of the base chip 10.

The insulating layers 31A and 31B may include a first insulating layer 31A and a second insulating layer 31B. The first insulating layer 31A may be disposed on the substrate 11 and cover the first integrated circuit IC. The second insulating layer 31B may be disposed on the first insulating layer 31A.

The first chip pad 82B may be disposed in the upper surface of the second insulating layer 31B. The first chip pad 82B may be connected to the first integrated circuit IC through a first via 81A and a wiring 82A disposed in the first insulating layer 31A and a second via 81B disposed in the second insulating layer 31B.

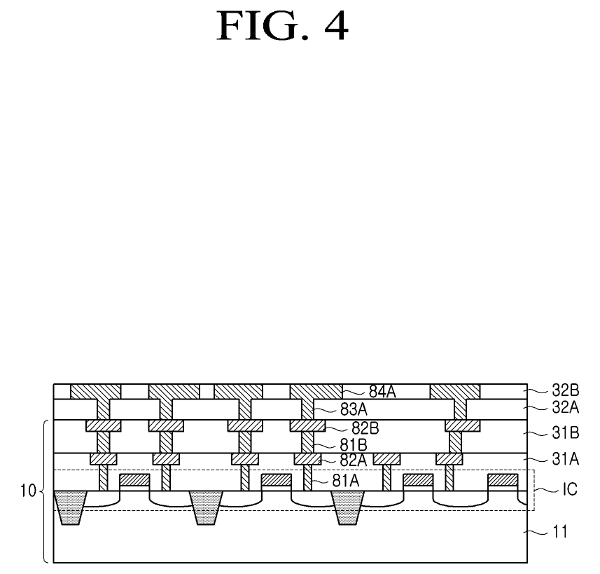

Referring to FIG. 4, a first redistribution insulating layer 32A, a second redistribution insulating layer 32B, a first redistribution via 83A and a first redistribution pattern 84A may be formed.

The first redistribution insulating layer 32A may be disposed on the base chip 10. The second redistribution insulating layer 32B may be disposed on the first redistribution insulating layer 32A. The second redistribution insulating layer 32B may include an insulating material that has an etching selectivity different from that of the first redistribution insulating layer 32A. The first redistribution insulating layer 32A may include nitride, and the second redistribution insulating layer 32B may include oxide.

The first redistribution via 83A may vertically penetrate the first redistribution insulating layer 32A. The first redistribution pattern 84A may vertically penetrate the second redistribution insulating layer 32B.

A process of forming the first redistribution via 83A and the first redistribution pattern 84A may include forming a first hole in the first redistribution insulating layer 32A and forming a first trench overlapping the first hole in the second redistribution insulating layer 32B, forming a first barrier metal layer to cover the surfaces of the first hole and the first trench, forming a first main metal layer on the first barrier metal layer to fill the first hole and the first trench, and removing the first barrier metal layer and the first main metal layer outside the first hole and the first trench.

The first barrier metal layer and the first main metal layer outside the first hole and the first trench may be removed by a chemical mechanical polishing (CMP) process. As the first barrier metal layer and the first main metal layer on the second redistribution insulating layer 32B are removed by the chemical mechanical polishing process, the upper surface of the second redistribution insulating layer 32B may be exposed.

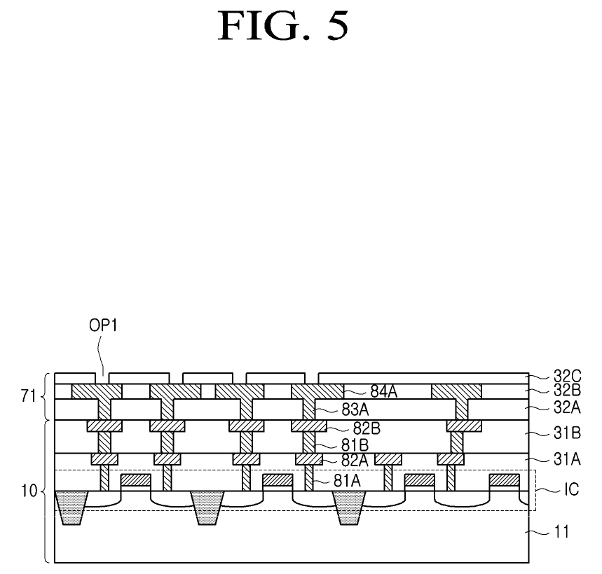

Referring to FIG. 5, a third redistribution insulating layer 32C may be formed.

The third redistribution insulating layer 32C may cover the second redistribution insulating layer 32B and have a first opening OP1 that partially exposes the first redistribution pattern 84A. The third redistribution insulating layer 32C may include oxide. The first opening OP1 may be formed by a photolithography process.

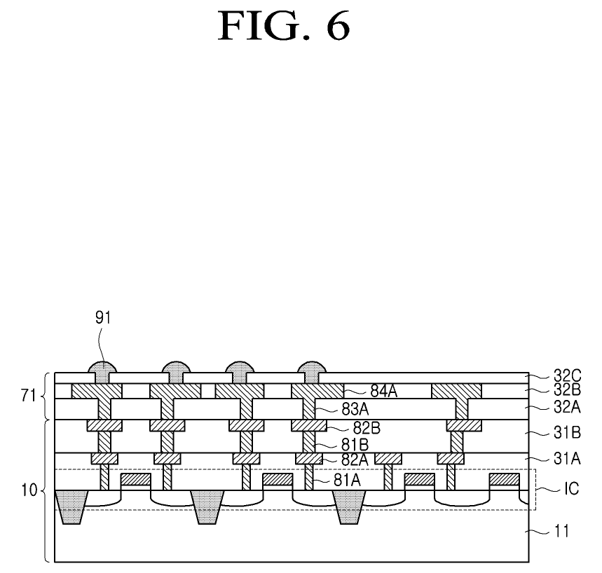

Referring to FIG. 6, a first bump 91 may be formed.

The first bump 91 may be disposed on the first redistribution pattern 84A exposed through the first opening OP1 (see FIG. 5). The first bump 91 may be a solder ball or a stack structure of a metal pillar and a solder layer.

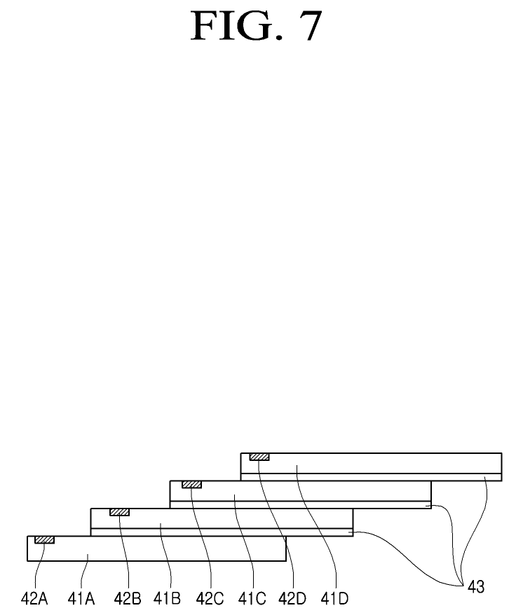

Referring to FIG. 7, first, second, third and fourth core chips 41A, 41B, 41C and 41D may be stacked.

The second core chip 41B may be stacked on the first core chip 41A, the third core chip 41C may be stacked on the second core chip 41B, and the fourth core chip 41D may be stacked on the third core chip 41C.

The first, second, third and fourth core chips 41A, 41B, 41C, and 41D may be memory chips. Each of the first, second, third and fourth core chips 41A, 41B, 41C, and 41D may include a second integrated circuit. The second integrated circuit may include memory cells. Second chip pads 42A, 42B, 42C, and 42D may be disposed close to the edges of the first, second, third and fourth core chips 41A, 41B, 41C, and 41D, respectively. The first, second, third and fourth core chips 41A, 41B, 41C, and 41D may be stacked in a stepwise manner such that the second chip pads 42A, 42B, 42C, and 42D are exposed. An adhesive member 43 may be disposed on the lower surface of each of the second, third and fourth core chips 41B, 41C, and 41D, and the core chips 41A, 41B, 41C, and 41D may be attached by the medium of adhesive members 43.

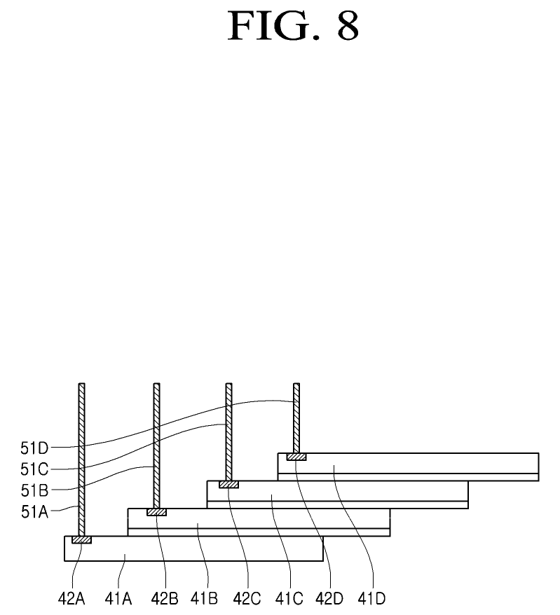

Referring to FIG. 8, first, second, third and fourth bonding wires 51A, 51B, 51C, and 51D may be formed on the first, second, third, and fourth core chips 41A, 41B, 41C, and 41D.

The first, second, third and fourth bonding wires 51A, 51B, 51C, and 51D may vertically extend with their lower ends connected to the corresponding second chip pads 42A, 42B, 42C, and 42D. The upper ends of the first, second, third, and fourth bonding wires 51A, 51B, 51C, and 51D may be disposed higher than the upper surface of the fourth core chip 41D. The first, second, third, and fourth bonding wires 51A, 51B, 51C, and 51D may be formed of a conductive material. The conductive material may include gold (Au).

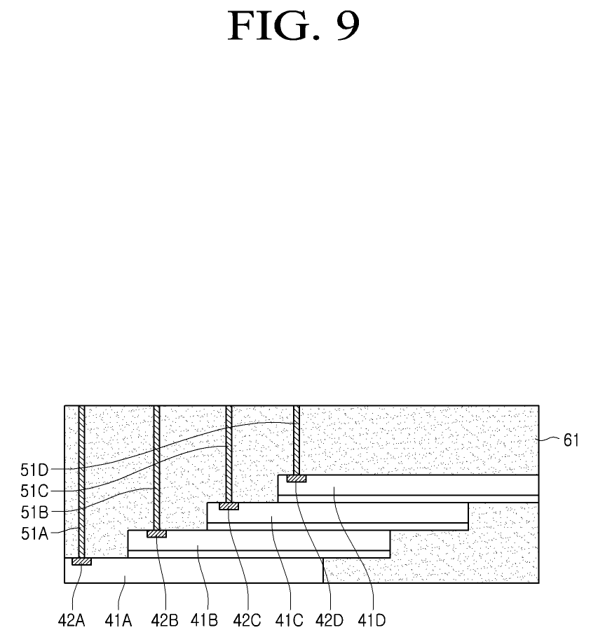

Referring to FIG. 9, a molding layer 61 may be formed.

The process of forming the molding layer 61 may include forming a pre-molding layer that covers the first, second, third, and fourth core chips 41A, 41B, 41C, and 41D and the first, second, third, and fourth bonding wires 51A, 51B, 51C, and 51D, and thinning the pre-molding layer to expose the upper ends of the first, second, third, and fourth bonding wires 51A, 51B, 51C, and 51D.

The pre-molding layer may be formed by a molding process using a liquid sealant. The molding process may include mounting the first, second, third, and fourth core chips 41A, 41B, 41C, and 41D formed with the first, second, third, and fourth bonding wires 51A, 51B, 51C, and 51D in a mold (not illustrated), introducing a liquid sealant into the mold, and curing the introduced sealant. The sealant may include an epoxy molding compound (EMC).

The thinning process may include a chemical mechanical polishing (CMP) process or a grinding process. By the thinning process, the upper ends of the first, second, third, and fourth bonding wires 51A, 51B, 51C, and 51D may be exposed at the upper surface of the molding layer 61.

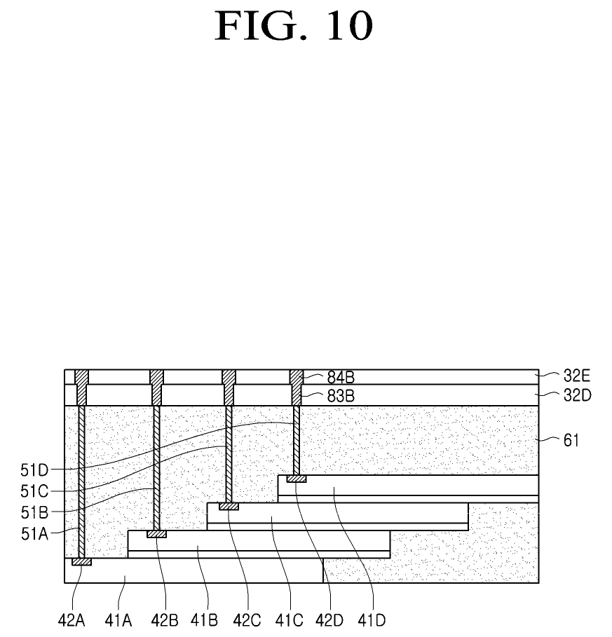

Referring to FIG. 10, a fourth redistribution insulating layer 32D, a fifth redistribution insulating layer 32E, a second redistribution via 83B and a second redistribution pattern 84B may be formed.

The fourth redistribution insulating layer 32D may be disposed on the molding layer 61. The fifth redistribution insulating layer 32E may be disposed on the fourth redistribution insulating layer 32D. The fifth redistribution insulating layer 32E may include an insulating material that has an etching selectivity different from that of the fourth redistribution insulating layer 32D. The fourth redistribution insulating layer 32D may include nitride, and the fifth redistribution insulating layer 32E may include oxide.

The second redistribution via 83B may vertically penetrate the fourth redistribution insulating layer 32D. The second redistribution pattern 84B may vertically penetrate the fifth redistribution insulating layer 32E.

A process of forming the second redistribution via 83B and the second redistribution pattern 84B may include forming a second hole in the fourth redistribution insulating layer 32D and forming a second trench overlapping the second hole in the fifth redistribution insulating layer 32E, forming a second barrier metal layer to cover surfaces of the second hole and the second trench, forming a second main metal layer on the second barrier metal layer to fill the second hole and the second trench, and removing the second barrier metal layer and the second main metal layer outside the second hole and the second trench.

The second barrier metal layer and the second main metal layer outside the second hole and the second trench may be removed by a chemical mechanical polishing (CMP) process. As the second barrier metal layer and the second main metal layer on the fifth redistribution insulating layer 32E are removed by the chemical mechanical polishing process, the upper surface of the fifth redistribution insulating layer 32E may be exposed.

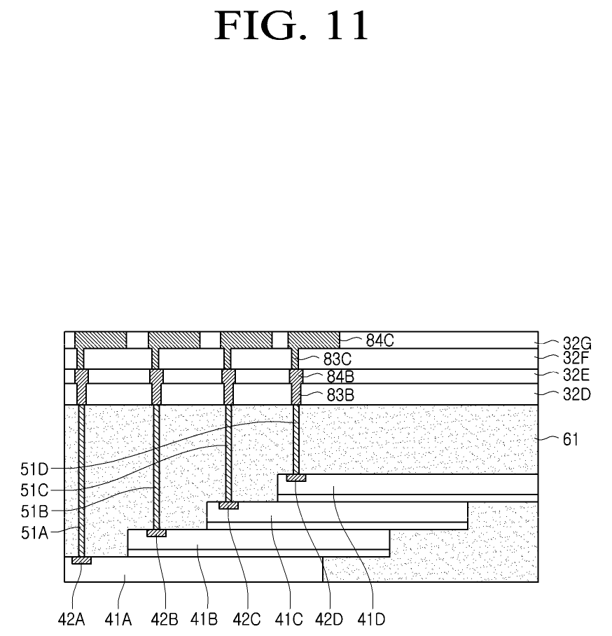

Referring to FIG. 11, a sixth redistribution insulating layer 32F, a seventh redistribution insulating layer 32G, a third redistribution via 83C and a third redistribution pattern 84C may be formed.

The sixth redistribution insulating layer 32F may be disposed on the fifth redistribution insulating layer 32E. The seventh redistribution insulating layer 32G may be disposed on the sixth redistribution insulating layer 32F. The seventh redistribution insulating layer 32G may include an insulating material that has an etching selectivity different from that of the sixth redistribution insulating layer 32F. The sixth redistribution insulating layer 32F may include nitride, and the seventh redistribution insulating layer 32F may include oxide.

The third redistribution via 83C may vertically penetrate the sixth redistribution insulating layer 32F. The third redistribution pattern 84C may vertically penetrate the seventh redistribution insulating layer 32G.

A process of forming the third redistribution via 83C and the third redistribution pattern 84C may include forming a third hole in the sixth redistribution insulating layer 32F and forming a third trench overlapping the third hole in the seventh redistribution insulating layer 32G, forming a third barrier metal layer to cover surfaces of the third hole and the third trench, forming a third main metal layer on the third barrier metal layer to fill the third hole and the third trench, and removing the third barrier metal layer and the third main metal layer outside the third hole and the third trench.

The third barrier metal layer and the third main metal layer outside the third hole and the third trench may be removed by a chemical mechanical polishing (CMP) process. As the third barrier metal layer and the third main metal layer on the seventh redistribution insulating layer 32G are removed by the chemical mechanical polishing process, the upper surface of the seventh redistribution insulating layer 32G may be exposed.

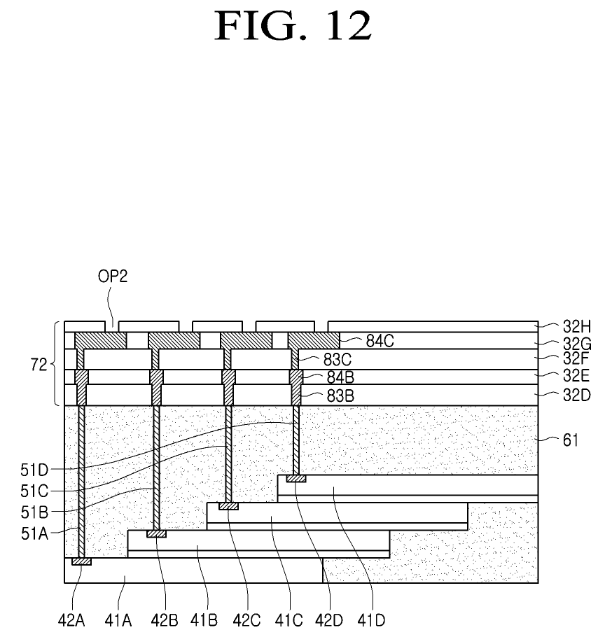

Referring to FIG. 12, an eighth redistribution insulating layer 32H may be formed.

The eighth redistribution insulating layer 32H may cover the seventh redistribution insulating layer 32G and have a second opening OP2 that partially exposes the third redistribution pattern 84C. The eighth redistribution insulating layer 32H may include oxide. The second opening OP2 may be formed by a photolithography process.

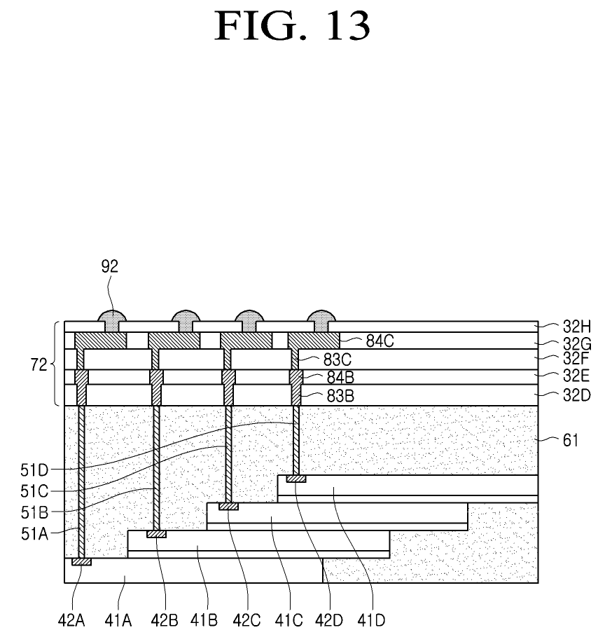

Referring to FIG. 13, a second bump 92 may be formed.

The second bump 92 may be disposed on the third redistribution pattern 84C exposed through the second opening OP2 (see FIG. 12). The second bump 92 may be a solder ball or a stack structure of a metal pillar and a solder layer.

Referring back to FIG. 1, the structure of FIG. 13 may be turned upside down, and the second bump 92 may be bonded onto the first bump 91. Thereafter, an underfill member 62 may be formed to fill a space between a first redistribution layer 71 and a second redistribution layer 72.

Hereafter, the effects of the present disclosure will be described.

Unlike the present disclosure, a semiconductor package may be formed by stacking a plurality of core chips on a base chip by the medium of bumps. In this case, when the number of core chips to be stacked increases, the number of bumps to be stacked increases by the number of core chips, and the semiconductor package may have a thicker thickness due to the presence of the bumps.

According to the present disclosure, because no bumps are disposed between core chips, the thickness of the semiconductor package may be reduced.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor package comprising:
a base chip;
a first redistribution layer disposed on the base chip;
a first bump disposed on the first redistribution layer;
a plurality of core chips stacked upon each other;
a second redistribution layer disposed below the plurality of core chips;
a plurality of bonding wires respectively disposed under the plurality of core chips, and respectively connecting the plurality of core chips and the second redistribution layer;
a molding layer disposed on the second redistribution layer, and disposed to cover the plurality of core chips and surround the plurality of bonding wires; and
a second bump disposed under the second redistribution layer and bonded onto the first bump.

2. The semiconductor package according to claim 1, wherein:
the base chip is a logic chip; and
each of the plurality of core chips is a memory chip.

3. The semiconductor package according to claim 1, wherein the plurality of core chips are stacked in a stepwise manner.

4. The semiconductor package according to claim 1, wherein the molding layer is disposed to expose an upper surface of an uppermost core chip among the plurality of core chips.

5. The semiconductor package according to claim 1, wherein the molding layer is disposed to expose one side surface of an uppermost core chip among the plurality of core chips and one side surface of a lowermost core chip among the plurality of core chips.

6. The semiconductor package according to claim 1, wherein each of the first and second bumps includes a solder layer.

7. The semiconductor package according to claim 1, wherein each of the first and second bumps has a structure in which a metal pillar and a solder layer are stacked.

8. The semiconductor package according to claim 1, further comprising
an underfill member disposed to fill a space between the first redistribution layer and the second redistribution layer, and surround the first and second bumps.

9. The semiconductor package according to claim 1, further comprising
adhesive members respectively disposed between the plurality of core chips to attach the plurality of core chips with each other.

10. A method of fabricating a semiconductor package, the method comprising:
forming a first redistribution layer on a base chip;
forming a first bump on the first redistribution layer;
stacking a plurality of core chips;
forming a plurality of bonding wires on the plurality of core chips;
forming a molding layer that covers the plurality of core chips and surrounds the plurality of bonding wires;
forming a second redistribution layer on the molding layer and the plurality of bonding wires;
forming a second bump on the second redistribution layer; and
bonding the second bump onto the first bump.

11. The method according to claim 10, wherein:
the base chip is a logic chip; and
each of the plurality of core chips is a memory chip.

12. The method according to claim 10, wherein in the stacking the plurality of core chips, the plurality of core chips are stacked in a stepwise manner.

13. The method according to claim 10, wherein in the stacking the plurality of core chips, each upper core chip and each lower core chip are attached to each other by a medium of each of adhesive members disposed under each of the plurality of core chips.

14. The method according to claim 10, wherein the molding layer is formed to expose an upper surface of an uppermost core chip among the plurality of core chips.

15. The method according to claim 10, wherein the molding layer is formed to expose one side surface of an uppermost core chip among the plurality of core chips and one side surface of a lowermost core chip among the plurality of core chips.

16. The method according to claim 10, wherein each of the first and second bumps includes a solder layer.

17. The method according to claim 10, wherein each of the first and second bumps has a structure in which a metal pillar and a solder layer are stacked.

18. The method according to claim 10, further comprising
forming an underfill member that fills a space between the first redistribution layer and the second redistribution layer and surrounds the first and second bumps.

19. A semiconductor package comprising:
a plurality of core chips stacked in a stair step formation;
a plurality of bonding wires, with lengths of each bonding wire defined by a place in an arrangement in the stair step formation, disposed under the plurality of core chips;
a first redistribution layer disposed on a base chip;
a first bump disposed on the first redistribution layer;
a molding layer covering the plurality of core chips and the plurality of bonding wires;
a second redistribution layer disposed below the molding layer and the plurality of bonding wires; and
a second bump disposed under the second redistribution layer and bonded onto the first bump.

20. The semiconductor package according to claim 19, wherein a length of each of the plurality of bonding wires is defined by a place of a particular bonding wire in the stair step formation.
